(19) United States
(12) Patent Application Publication
(10) Pub. No.: US 2010/0061072 A1
(43) Pub. Date: Mar. 11, 2010

(54) MULTI-LAYER PRINTED CIRCUIT BOARD

(75) Inventors: Masaharu Imazato, Minato-ku (JP); Takao Ono, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignees: NEC CORPORATION, Minato-ku, Tokyo (JP); ELPIDA MEMORY, INC., Chuo-ku, Tokyo (JP)

(21) Appl. No.: 12/374,602

(22) PCT Filed: Jul. 11, 2007
(86) PCT No.: PCT/JP2007/063861

§ 371 Date: Nov. 9, 2009

(30) Foreign Application Priority Data
Jul. 19, 2006 (JP) 2006-196465

(51) Int. Cl. H05K 1/11

(52) U.S. Cl. 361/803; 174/262

(57) ABSTRACT

Ground via provided in an end portion of a multi-layer printed circuit board so as to suppress a leakage of magnetic field from the end portion of the board causes a problem that a digital circuit of high density cannot be mounted on the board due to necessity of area for locating the ground via. Further, a case of using solder plating for the end portion of the board causes a problem that manufacturing process is added and that numbers of days and costs for manufacturing the multi-layer printed circuit board are increased.

In a multi-layer printed circuit board has a plurality of ground layers and at least one signal layer, the signal layer in which a signal pattern is wired at an end portion of the multi-layer printed circuit board is sandwiched between upper adjacent and lower adjacent ground layers, and the upper adjacent and lower adjacent ground layers are connected to each other by recessed conductors at the end portion thereof. In addition, an interval between the recessed conductors is not larger than λ/8 of a higher harmonic frequency as an operable frequency.

### TECHNICAL FIELD

The present invention relates to a multi-layer printed circuit board on which an electronic device is mounted, in particular to a multi-layer printed circuit board which is capable of reducing amount of radiation of noises or electromagnetic waves from the circuit board.

### BACKGROUND TECHNIQUE

In an apparatus on which an electronic device is mounted, a multi-layer printed circuit board has been conventionally used in order to make the apparatus be small in size. Further, in recent years, as regards the apparatus on which the electronic device is mounted, wiring density of the multi-layer printed circuit board is becoming higher with a tendency of requiring higher density and higher function. Therefore, wiring design is implemented by the maximum use of the whole plane of the board. Furthermore, a digital circuit is employed as the printed circuit with a tendency of requiring higher speed and the higher function.

In the digital circuit, noises due to high frequency signal components of the digital circuit are radiated from the printed circuit board. As regards noises radiated from a digital circuit, amount of radiation of the noises is restricted so as not to influence the other devices. For making this restricted value be satisfied, the non-patent reference 1 described below is known as a means for reducing radiation of the noises. In the non-patent reference 1, a means called “20 H rule” is described as the means for reducing radiation of the noises from the printed circuit board. The 20 H rule is a method that a pattern area of a power supply plane is designed by twenty times of a thickness, H of a dielectric body between the power supply plane and the ground plane as small as a pattern area of a ground plane in the multi-layer printed circuit board. Namely, leakage of magnetic field from an end portion of the multi-layer printed circuit board is suppressed by making the ground plane be larger.

In order to comply with the 20 H rule, it is necessary to provide the end portion of the multi-layer printed circuit board with an area incapable of wiring. In the multi-layer printed circuit board having a high wiring density, it is dangerous to be unable to contain a necessary digital circuit within a board area thereof. For example, it is presumed that a thickness of a dielectric body between layers is 0.1 mm in a multi-layer printed circuit board for use in a memory module mounted on a personal computer, such as a notebook PC, and the like. In this case, in order to comply with the 20H rule, the area incapable of wiring is generated by a width of 2 mm from the end portion of the multi-layer printed circuit board for use in the memory module. Since an external size of the multi-layer printed circuit board for use in the memory module is standardized, the multi-layer printed circuit board for use in the memory module has a standard size. Accordingly, the 20H rule causes a possibility that the necessary circuit cannot be mounted.

Further, as a second conventional technique suppressing the leakage of magnetic field from the end portion of the multi-layer printed circuit board without applying the above-described 20 H rule, there is a method of shielding the end portion thereof. In the method, the multi-layer printed circuit board has, for example, a structure that a signal layer is sandwiched between two grand layers. The multi-layer printed circuit board consisting of a ground layer, a signal layer, and a ground layer is assumed therein. In the multi-layer printed circuit board, since the two ground layers are connected at the end portion of the board by ground via or solder plating, the leakage of magnetic field from the signal layer can be suppressed.

These second conventional techniques are explained with reference to FIGS. 3 through 5. In FIG. 3, illustrated is a structural view of a multi-layer printed circuit board in which the two ground layers are connected at the end portion of the board by the ground via. In FIG. 4, illustrated is a cross sectional view taken from A-A′ line of FIG. 3. In FIG. 5, illustrated is a structural view of a multi-layer printed circuit board in which the two ground layers are connected at the end portion of the board by the solder plating.

The multi-layer printed circuit board illustrated in FIG. 3 and FIG. 4 comprises a ground layer 31 as a first layer, a signal layer 32 as a second layer, and a ground layer 33 as a third layer. A signal pattern 34 is wired at the end portion of the signal layer 32 of the multi-layer printed circuit board. A plurality of grand via 35 are arranged at a further end portion side than the signal pattern 34. The upper and lower ground layers 31 and 33 as the first and the third layers are connected by the plurality of grand via 35. Upper and lower sides of the signal pattern 34 are sandwiched by the ground layer 31 as the first layer and the ground layer 33 as the third layer. In addition, the ground via 35 is located at the side of a side plane of the signal pattern 34. The signal pattern 34 is shielded by an electric potential of the ground around the signal pattern 34, so that the leakage of magnetic field from the signal layer is suppressed.

Similarly, the multi-layer printed circuit board illustrated in FIG. 5 comprises a ground layer 51 as a first layer, a signal layer 52 as a second layer, and a ground layer 53 as a third layer. A signal pattern 54 is wired at the end portion of the signal layer 52 of the multi-layer printed circuit board. The upper and lower ground layers 51 and 53 as the first and the third layers are connected by the solder plating 55 of an end portion of the board and near the signal pattern 54. Upper and lower sides of the signal pattern 54 are sandwiched by the ground layer 51 as the first layer and the ground layer 53 as the third layer. In addition, the solder plating 55 is located at the side of a side plane of the signal pattern 54. The signal pattern 54 is shielded by an electric potential of the ground around the signal pattern 54, so that the leakage of magnetic field from the signal layer is suppressed.

Patent references described below are reported as prior art references relating to the above-described techniques. A patent reference 1 (An official gazette of an unexamined Japanese patent publication Hei 11-330298: Package provided with signal terminal and electronic device using the package) discloses a technique that a floating capacity between a signal terminal and a grounding terminal is reduced. A recessed part or a hole is provided between the signal terminal and the grounding terminal formed on the side plane of a base, so that a floating capacity is reduced. Thereby, a high frequency characteristic can be prevented from being deteriorated.

Further, a patent reference 2 (An official gazette of an unexamined Japanese patent publication 2004-128309: Module component) discloses a technique that miniaturization of a module component can be secured even when the number of input/output signals increases. In a module component consisting of a circuit board formed directly under a mounting component, a ground pattern is formed so as to surround the connection electrode formed on the surface of the circuit board. Thereby, an excellent characteristic of high frequency is obtained while keeping the miniaturization, and the module component is miniaturized.

Further, a patent reference 3 (An official gazette of an unexamined Japanese patent publication 2002-299781: Circuit substrate)-discloses a technique capable of accurately measuring characteristics of a circuit function element inside the circuit substrate, without lowering the jointing strength of the circuit substrate to a mother board. Ground end face electrodes and a jointing auxiliary terminal electrode are disposed at an end face of a large circuit substrate in which a plurality of circuit substrates are arranged, and an independent signal electrode is disposed on a rear face of the circuit substrate. A circuit substrate thereby capable of accurately measuring characteristics of a circuit element inside the circuit substrate is proposed in the patent reference 3.

Further, a patent reference 4 (An official gazette of a Japanese patent No. 3638479: High frequency wiring board and connecting structure thereof) discloses a technique providing a high frequency wiring board and connecting structure thereof capable of preventing the occurrence of resonance between a via hole conductor and the end surface of a dielectric board and thereby of reducing transmission loss at a frequency not lower than 30 GHz. A pair of connecting ground conductors are formed on both sides of a signal conductor line. By making a distance between the connecting ground conductor and the signal conductor line be not larger than 0.25 λg, a board and a structure having an excellent high frequency characteristic are proposed in the patent reference 4.

Further, a patent reference 5 (An official gazette of an unexamined Japanese patent publication Hei 8-264915: Wiring board) discloses a technique providing a wiring board which can be used for both surface mounting and inserting component mounting. Recessed sections and recessed conductive sections are formed on the end faces of the board while land sections are provided on both the front and rear surfaces of the board. A wiring board thereby capable of being used for both surface mounting and inserting component mounting is proposed in the patent reference 5.

Further, a patent reference 6 (An official gazette of an unexamined Japanese patent publication Hei 5-160526: Printed circuit board) discloses a technique providing a printed circuit board having a high insulation between a shield case and a wiring pattern. The peripheral part of the board and the plated leads for plating process are notched, thereby forming plated lead cut parts having a substantially semicircular shape. The printed circuit board thereby capable of having a high insulation is proposed in the patent reference 6.

Further, a patent reference 7 (An official gazette of an examined Japanese patent publication Hei 7-36464: End-plated printed wiring board and a method of manufacturing the same) discloses a technique providing an end-plated printed wiring board capable of preventing ends of plating layers from being irregular and peeling off. A plurality of slits are formed in a workboard having a larger size than that of outer configuration of a printed board in line with outer peripheral of the board portion. A plating layer is formed in each of the slits and then the outer peripheral is cut between the slits. The end-plated printed wiring board thereby capable of preventing the ends of plating layers from being irregular and peeling off is proposed in the patent reference 7.

However, techniques disclosed in these patent references are such techniques for miniaturization and improving high frequency characteristics. The patent references never disclose a technique for intentionally suppressing a leakage of magnetic field from an end portion of a board.

Further, a patent reference 8 (An official gazette of an unexamined Japanese patent publication Hei 8-162853: Slot line type single balance mixer) discloses a technique for improving the frequency characteristic of a conversion loss of a mixer while keeping shield performance of the mixer circuit and shield performance to an external device. The patent reference 8 proposes a mixer that a mixer circuit is formed on a four-layers printed circuit board, that ground patterns are formed on substantially entire faces of the internal layers while ground conversion throughholes for ground conversion are formed on the other internal layers, and that a length l from the ground conversion throughholes is regulated to be L<λ/8. However, it is necessary to have a side-plating process after forming a multi-layer printed circuit board for the side-plating of the end portion of the board. The mixer causes a new problem that the number of days and cost for manufacturing the mixer are increased.

Furthermore, references described below are existing as patent references relating to the leakage of magnetic field. A patent reference 9 (An official gazette of an unexamined Japanese patent publication Hei 7-263871: Printed wiring board) discloses a printed wiring board that throughholes are densely arranged along the peripheral edge of the board and that conductor layers provided on both front and rear surfaces are connected by the throughholes. Similar techniques are also described in the other patent references 10, 11, 12 (an unexamined Japanese patent publication 2001-068801, an unexamined Japanese patent publication 2005-302799, an unexamined Japanese utility model publication Sho 64899). These structures are shown in FIGS. 3 and 4 as conventional examples. Further, the structure shown in FIG. 5 in which the end portion of the board is plated is also shown in the patent references. Besides, a non-patent reference 1 generally discloses the above-mentioned 20 H rule.
Patent reference 1: An official gazette of an unexamined Japanese patent publication Hei 11-330298
Patent reference 2: An official gazette of an unexamined Japanese patent publication 2004-128309
Patent reference 3: An official gazette of an unexamined Japanese patent publication 2002-299781
Patent reference 4: An official gazette of a Japanese patent No.
Patent reference 5: An official gazette of an unexamined Japanese patent publication Hei 8-264915
Patent reference 6: An official gazette of an unexamined Japanese patent publication Hei 5-160526
Patent reference 7: An official gazette of an examined Japanese patent publication Hei 7-36464
Patent reference 8: An official gazette of an unexamined Japanese patent publication Hei 8-162853
Patent reference 9: An official gazette of an unexamined Japanese patent publication Hei 7-263871
Patent reference 10: An official gazette of an unexamined Japanese patent publication 2001-068801
Patent reference 11: An official gazette of an unexamined Japanese patent publication 2005-302799
Patent reference 12: An official gazette of an unexamined Japanese utility model publication Sho 64-399
Non-patent reference 1: EMC design of printed circuit, Author: Mark I. Montrose, Co-translators: Hirokazu Deguchi, Masateru tagami, Issued by Ohm Corporation (Page 29, The 2.2 item)

### DISCLOSURE OF THE INVENTION

### Problem to be Solved by the Invention

As described above, the 20 H rule is existing as a technique suppressing the leakage of magnetic field from a circuit board. However, according to this 20 H rule, it is necessary to provide the end portion of the multi-layer printed circuit board with an area incapable of wiring. Therefore, the whole of the multi-layer printed circuit board cannot be used effectively. This causes a problem that a necessary digital circuit cannot be contained within the board thereof. Further, shown in FIGS. 3 and 4, as the second technique, is a method that a signal wiring is shielded by an electric potential of the ground. However, the multi-layer printed circuit board according to the second technique also causes a problem that a necessary digital circuit cannot be contained within the board thereof.

According to the second technique, it becomes necessary to have not only a clearance between the signal pattern and the ground via but also a clearance between the ground via and the end portion of the board. Therefore, a space between the signal pattern and the end portion of the board becomes large. Further, in the multi-layer printed circuit board shown in FIG. 5, a process of solder plating for the end portion of the board is additionally required after forming a multi-layer printed circuit board consisting of a ground layer, a signal layer and a ground layer. This causes a new problem that the number of days and costs for manufacturing the multi-layer printed circuit board are increased.

In view of these problems, it is an object of the present invention to provide a multi-layer printed circuit board capable of suppressing the leakage of magnetic field from the circuit board.

### Means for Solving the Problem

In order to solve the above-described problems, the present application basically employs techniques described below. Further, it is needless to say that applied techniques capable of variously being changed within a range not exceeding its technical concept are included in the present application.

According to the present invention, a multi-layer printed circuit board comprising: a plurality of ground layers; at least one signal layer; the signal layer in which a signal pattern is wired at an end portion of the multi-layer printed circuit board being sandwiched between upper adjacent and lower adjacent ground layers; and the upper adjacent and lower adjacent ground layers being connected to each other by a recessed conductor at the end portion thereof.

In the multi-layer printed circuit board according to the present invention, a plurality of the recessed conductors are provided.

In the multi-layer printed circuit board according to the present invention, an interval between the recessed conductors is not larger than λ/8 of a higher harmonic frequency as an operable frequency.

According to the present invention, a multi-layer printed circuit board comprising: a plurality of ground layers; at least one power supply layer; the power supply layer in which a power supply pattern is wired at an end portion of the multi-layer printed circuit board being sandwiched between upper adjacent and lower adjacent ground layers; and the upper adjacent and lower adjacent ground layers being connected to each other by a recessed conductor at the end portion thereof.

In the multi-layer printed circuit board according to the present invention, a plurality of the recessed conductors are provided.

In the multi-layer printed circuit board according to the present invention, an interval between the recessed conductors is not larger than λ/8 of a higher harmonic frequency as an operable frequency.

According to the present invention, a work board comprising: a plurality of multi-layer printed circuit boards located on the work board; each of a plurality of multi-layer printed circuit boards having: a plurality of ground layers, at least one signal layer, the signal layer in which a signal pattern is wired at an end portion of the multi-layer printed circuit board being sandwiched between upper adjacent and lower adjacent ground layers, and the upper adjacent and lower adjacent ground layers being connected to each other at the end portion of each of a plurality of multi-layer printed circuit boards by a plurality of cut holes which have been through-hole plated.

According to the present invention, in the multi-layer printed circuit board obtained from the work board, the work board is scribed between a plurality of cut holes and divided into each of a plurality of multi-layer printed circuit boards.

In the multi-layer printed circuit board according to the present invention, an interval between a plurality of cut holes is not larger than λ/8 of a higher harmonic frequency as an operable frequency.

According to the present invention, a work board comprising: a plurality of multi-layer printed circuit boards located on the work board; each of a plurality of multi-layer printed circuit boards having; a plurality of ground layers, at least one power supply layer, the power supply layer in which a power supply pattern is wired at an end portion of the multi-layer printed circuit board being sandwiched between upper adjacent and lower adjacent ground layers, and the upper adjacent and lower adjacent ground layers being connected to each other at the end portion of each of a plurality of multi-layer printed circuit boards by a plurality of cut holes which have been through-hole plated.

According to the present invention, in the multi-layer printed circuit board obtained from the work board, the work board is scribed between a plurality of cut holes and divided into each of a plurality of multi-layer printed circuit boards.

In the multi-layer printed circuit board according to the present invention, an interval between a plurality of cut holes is not larger than λ/8 of a higher harmonic frequency as an operable frequency.

### EFFECTS OF THE INVENTION

According to the present invention, a multi-layer printed circuit board comprises a plurality of ground layers and at least one signal layer. The signal layer is sandwiched between upper adjacent and lower adjacent ground layers. In addition, the upper adjacent and lower adjacent ground layers are connected to each other by a plurality of recessed conductors at the end portion of the board. An interval between these a plurality of recessed conductors is not larger than λ/8 of a higher harmonic frequency as an operable frequency. The signal layer is shielded by the upper adjacent and the lower adjacent ground layers and the recessed conductors at the end portion of the board. This produces an effect that a leakage of magnetic field is suppressed. Further, since the interval between the recessed conductors is not larger than λ/8 of a higher harmonic frequency, it is possible to suppress also a leakage of magnetic field in a higher harmonic frequency component which is as times as an operable frequency. Thus, the leakage of magnetic field from the end portion of the board is not caused to occur. The standard rule of radiation noise can be satisfied as an electronic device mounting apparatus on which the multi-layer printed circuit board is mounted.

Further, the recessed conductors are provided at the end portion of the board, and thereby a space between the end portion and the wiring pattern can be made small. It therefore becomes possible to make a multi-layer printed circuit board be small in size. Furthermore, manufacturing cost is not increased by forming the recessed conductors at the same time as a through hole process of the board. According to the present invention, not only a leakage of magnetic field in a higher harmonic frequency component of an operable frequency can be suppressed but also a compact and cheap multi-layer printed circuit board can be obtained.

### BRIEF DESCRIPTION OF THE DRAWINGS

FIG. 1 A perspective view for showing a multi-layer printed circuit board according to an embodiment 1 of the present invention.

FIG. 2 A plan view of each layer of the multi-layer printed circuit board according to the embodiment 1 of the present invention.

FIG. 3 A structural view for showing a multi-layer printed circuit board of a conventional technique.

FIG. 4 A cross sectional view for showing a multi-layer printed circuit board of a conventional technique.

FIG. 5 A cross sectional view for showing a multi-layer printed circuit board of a conventional technique.

FIG. 6 A plan view for showing a work board according to an embodiment 2 of the present invention.

FIG. 7 A plan view for showing a work board according to an embodiment 3 of the present invention.

FIG. 8 A characteristic view of difference of the maximum magnetic field strength, when L=3 mm in the multi-layer printed circuit board according to the embodiment 1 of the present invention.

FIG. 9 A characteristic view of difference of the maximum magnetic field strength, when L=7 mm in the multi-layer printed circuit board according to the embodiment 1 of the present invention.

FIG. 10 A distribution view of 1 GHz magnetic field strength in the multi-layer printed circuit board according to the embodiment 1 of the present invention, wherein (A) no recessed conductor, (B) recessed conductor of L=3 mm.

FIG. 11 A distribution view of 2 GHz magnetic field strength in the multi-layer printed circuit board according to the embodiment 1 of the present invention, wherein (A) no recessed conductor, (B) recessed conductor of L=3 mm.

FIG. 12 A distribution view of 3 GHz magnetic field strength in the multi-layer printed circuit board according to the embodiment 1 of the present invention, wherein (A) no recessed conductor, (B) recessed conductor of L=3 mm.

FIG. 13 A distribution view of 4 GHz magnetic field strength in the multi-layer printed circuit board according to the embodiment 1 of the present invention, wherein (A) no recessed conductor, (B) recessed conductor of L=3 mm.

FIG. 14 A distribution view of 5 GHz magnetic field strength in the multi-layer printed circuit board according to the embodiment 1 of the present invention, wherein (A) no recessed conductor, (B) recessed conductor of L=3 mm.

FIG. 15 A distribution view of 6 GHz magnetic field strength in the multi-layer printed circuit board according to the embodiment 1 of the present invention, wherein (A) no recessed conductor, (B) recessed conductor of L=3 mm.

FIG. 16 A distribution view of 7 GHz magnetic field strength in the multi-layer printed circuit board according to the embodiment 1 of the present invention, wherein (A) no recessed conductor, (B) recessed conductor of L=3 mm.

FIG. 17 A distribution view of 8 GHz magnetic field strength in the multi-layer printed circuit board according to the embodiment 1 of the present invention, wherein (A) no recessed conductor, (B) recessed conductor of L=3 mm.

FIG. 18 A distribution view of 9 GHz magnetic field strength in the multi-layer printed circuit board according to the embodiment 1 of the present invention, wherein (A) no recessed conductor, (B) recessed conductor of L=3 mm.

FIG. 19 A distribution view of 10 GHz magnetic field strength in the multi-layer printed circuit board according to the embodiment 1 of the present invention, wherein (A) no recessed conductor, (B) recessed conductor of L=3 mm.

FIG. 20 A distribution view of 1 GHz magnetic field strength in the multi-layer printed circuit board according to the embodiment 1 of the present invention, wherein (A) no recessed conductor, (B) recessed conductor of L=7 mm.

FIG. 21 A distribution view of 2 GHz magnetic field strength in the multi-layer printed circuit board according to the embodiment 1 of the present invention, wherein (A) no recessed conductor, (B) recessed conductor of L=7 mm.

FIG. 22 A distribution view of 3 GHz magnetic field strength in the multi-layer printed circuit board according to the embodiment 1 of the present invention, wherein (A) no recessed conductor, (B) recessed conductor of L=7 mm.

FIG. 23 A distribution view of 4 GHz magnetic field strength in the multi-layer printed circuit board according to the embodiment 1 of the present invention, wherein (A) no recessed conductor, (B) recessed conductor of L=7 mm.

FIG. 24 A distribution view of 5 GHz magnetic field strength in the multi-layer printed circuit board according to the embodiment 1 of the present invention, wherein (A) no recessed conductor, (B) recessed conductor of L=7 mm.

FIG. 25 A distribution view of 6 GHz magnetic field strength in the multi-layer printed circuit board according to the embodiment 1 of the present invention, wherein (A) no recessed conductor, (B) recessed conductor of L=7 mm.

FIG. 26 A distribution view of 7 GHz magnetic field strength in the multi-layer printed circuit board according to the embodiment 1 of the present invention, wherein (A) no recessed conductor, (B) recessed conductor of L=7 mm.

### DESCRIPTION OF REFERENCE NUMERALS

1, 3, 31, 33, 51, 53 ground layer
2,32,52 signal layer
4,34,54 signal pattern
5 end portion of a board
6 recessed conductor
7 recessed portion
35 ground via
55 solder plating
61,71 work board
62,72 printed circuit board
63,73 through-hole plated cut hole
64,74 cut line
101 multi-layer printed circuit board (no recessed conductor)
102 multi-layer printed circuit board (recessed conductor, L=3 mm)
103 multi-layer printed circuit board (recessed conductor, L=7 mm)

### BEST MODE FOR CARRYING OUT THE INVENTION

Description will be made about a best mode for carrying out the present invention with reference to the drawings.

### Embodiment 1

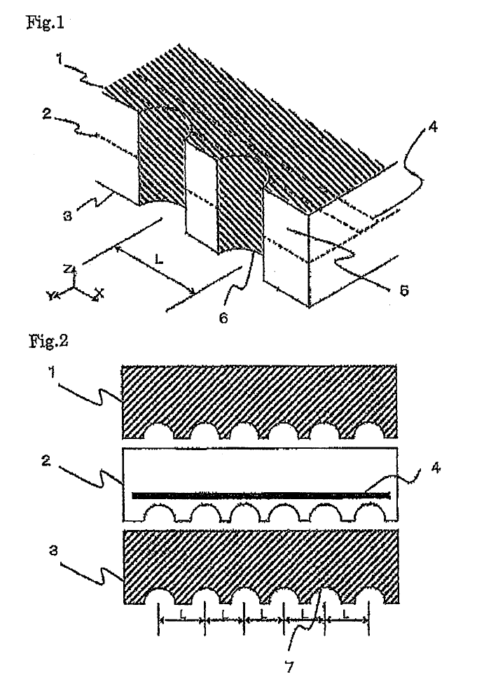

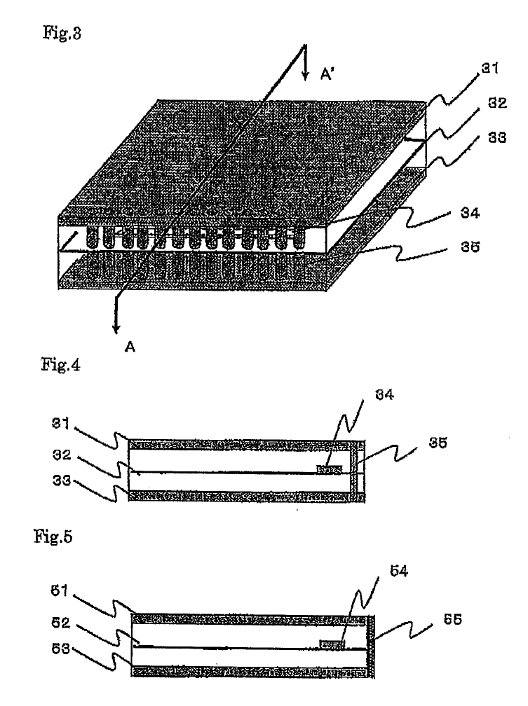

Referring to the drawings, detailed description will be made as regards an embodiment 1 according to the present invention. FIG. 1 is a perspective view for showing a multi-layer printed circuit board according to the embodiment 1 of the present invention. FIG. 2 is a plan view of each layer thereof.

The multi-layer printed circuit board illustrated in FIG. 1 comprises a ground layer 1 as a first layer, a signal layer 2 as a second layer, and a ground layer 3 as a third layer. In the signal layer 2, a signal pattern 4 is wired near an end portion of the multi-layer printed circuit board. Further, the multi-layer printed circuit board comprises a plurality of semi-circular recessed portions 7 on the end portion 5 of the board. Recessed conductors 6 are arranged on surfaces of the recessed portions 7, respectively. The ground layer 1 as the first layer and the ground layer 3 as the third layer are connected by the recessed conductors 6. Herein, each interval between a plurality of recessed conductors 6 or a plurality of recessed portions 7 is a length L.

FIG. 2 are plan views of each of the layers of the multi-layer printed circuit board illustrated in FIG. 1. FIG. 2 show the ground layer 1 as the first layer, the signal layer 2 as the second layer, and the ground layer 3 as the third layer, respectively, in order from the upper side of FIG. 2. Conductor patterns are provided on whole planes of the ground layers 1 and 3. The signal pattern 4 is wired on an area of the lower side of the signal layer 2 and near the end portion of the board. A signal wire or a power supply wire is arranged as the signal pattern of the signal layer 2. The recessed portions 7 having the recessed conductors 6, respectively, are arranged on end portions of the ground layer 1 as the first layer, the signal layer 2 as the second layer and the ground layer 3 as the third layer. The recessed portions 7 of the respective layers are connected by conductors to form the recessed conductors 6 illustrated in FIG. 1.

The multi-layer printed circuit board according to the present invention is characterized in that the multi-layer printed circuit board comprises a plurality of ground layers and at least one signal layer. The signal pattern wired near the end portion of the board in the signal layer is sandwiched between the upper adjacent and the lower adjacent ground layers. In addition, the upper adjacent and the lower adjacent ground layers are connected to each other by the recessed conductors at the end portion of the board.

### Embodiment 2

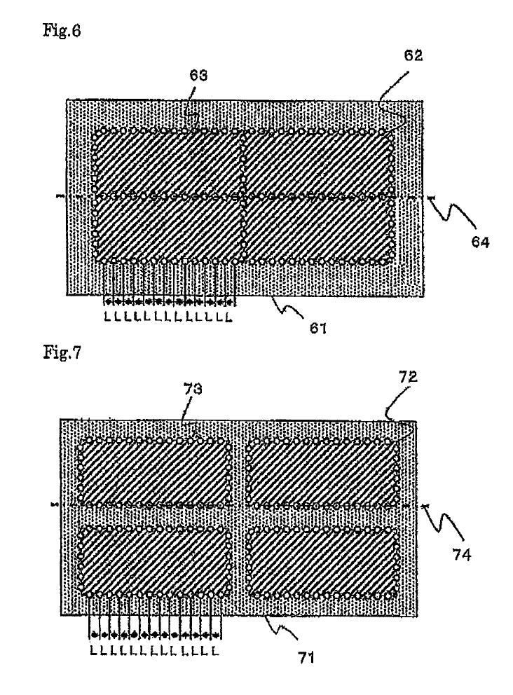

As an embodiment 2 according to the present invention, referring to FIG. 6, detailed description will be made as regards a structure of a work board in which a plurality of the multi-layer printed circuit boards are arranged. FIG. 6 is a plan view for showing a-work board in which a plurality of the multi-layer printed circuit boards are arranged according to the embodiment 2 of the present invention.

In FIG. 6, a plurality of the multi-layer printed circuit boards 62 are arranged in the work board 61. A plurality of cut holes 63 which have been through-hole plated are provided in respective circumferentially end portions of the multi-layer printed circuit boards 62. The cut holes 68 which have been through-hole plated are co-owned by and between the multi-layer printed circuit boards 62 adjacent to each other. The cut holes 63 of one line serve as the cut holes for two printed circuit boards. Each interval between a plurality of the cut holes 63 which have been through-hole plated is a length L.

In order to divide the work board 61 into the respective multi-layer printed circuit boards 62, the work board 61 is scribed in line with a scribed line 64. The cut holes 63 which have been through-hole plated of each of the multi-layer printed circuit boards 62 after being scribed become the recessed conductors by having been scribed. Although not shown in FIG. 6, each of the multi-layer printed circuit boards 62 comprises the ground layer as the first layer, the signal layer as the second layer, and the ground layer as the third layer. In the signal layer, the signal pattern is wired in the area near the end portion of the board.

A plurality of the multi-layer printed circuit boards are located in the structure of the work board according to the embodiment 2 of the present invention. The multi-layer printed circuit boards adjacent to each other co-own the cut holes 63 which have been through-hole plated. By scribing the work board along the cut holes 63 which have been through-hole plated thus co-owned, the work board is divided into the respective multi-layer printed circuit boards. The cut holes 63 which have been through-hole plated of each of the multi-layer printed circuit boards become the recessed conductors by having been scribed.

### Embodiment 3

As an embodiment 3 according to the present invention, referring to FIG. 7, detailed description will be made as regards a structure of a work board in which a plurality of the multi-layer printed circuit boards are arranged. FIG. 7 is a plan view for showing a work board in which a plurality of the multi-layer printed circuit boards are arranged according to the embodiment 3 of the present invention.

In Figure, a plurality of the multi-layer printed circuit boards 72 are arranged in the work board 71. A plurality of cut holes 73 which have been through-hole plated are provided in respective circumferentially end portions of the multi-layer printed circuit boards 72. Each interval between a plurality of the cut holes 73 which have been through-hole plated is a length L. In order to divide the work board 71 into the respective multi-layer printed circuit boards 72, the work board 71 is scribed in line with a scribed line 74. The cut holes 73 which have been through-hole plated of each of the multi-layer printed circuit boards 72 after being scribed become the recessed conductors by having been scribed. Although not shown in FIG. 7, each of the multi-layer printed circuit boards 72 comprises the ground layer as the first layer, the signal layer as the second layer, and the ground layer as the third layer. In the signal layer, the signal pattern is wired in the area near the end portion of the board.

A plurality of the multi-layer printed circuit boards are located in the structure of the work board according to the embodiment 3 of the present invention. A plurality of cut holes 73 which have been through-hole plated are provided in respective circumferentially end portions of the multi-layer printed circuit boards 72. By scribing the work board along the cut holes 73 which have been through-hole plated, the work board is divided into the respective multilayer printed circuit boards. The cut holes 73 which have been through-hole plated of each of the multi-layer printed circuit boards become the recessed conductors by having been scribed.

### Example 1

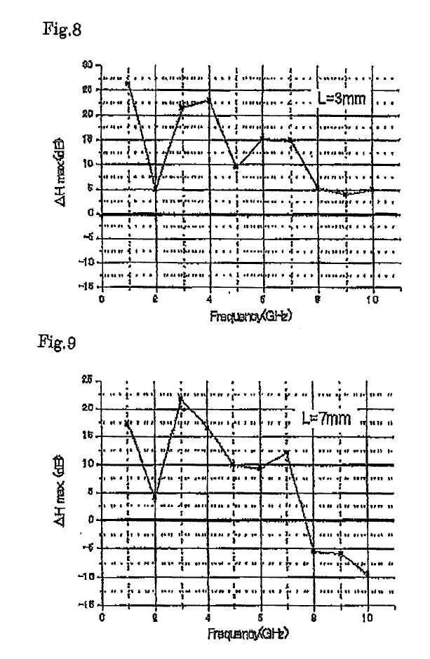

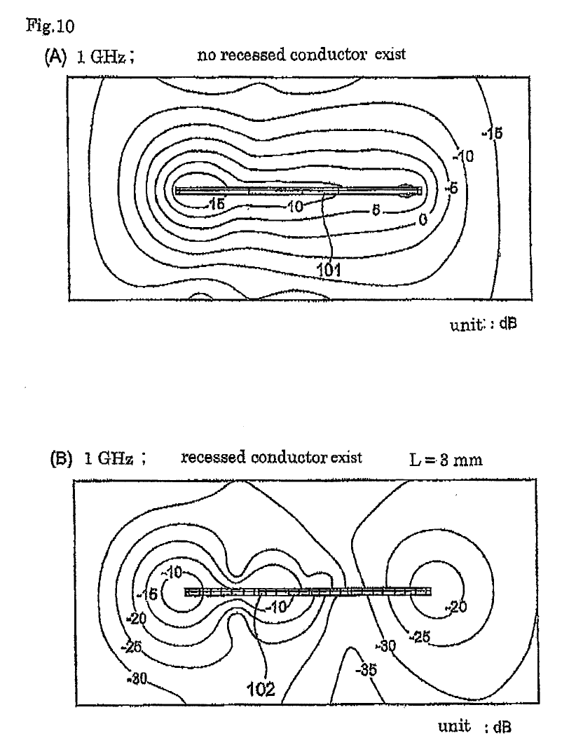

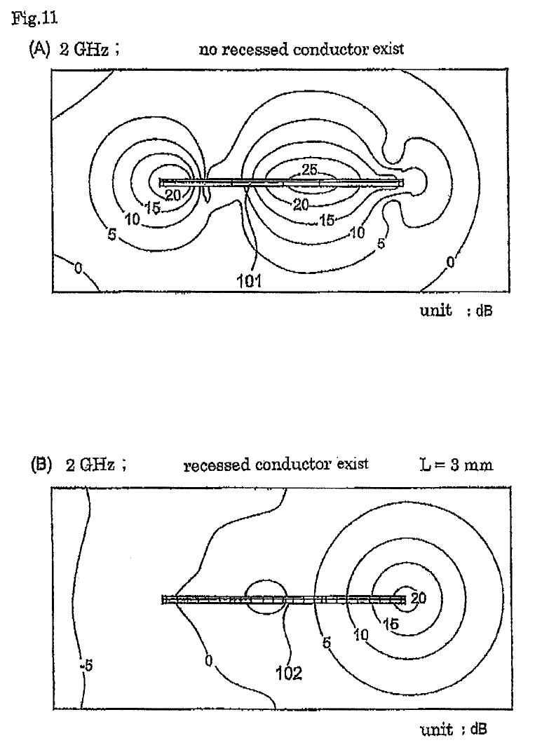

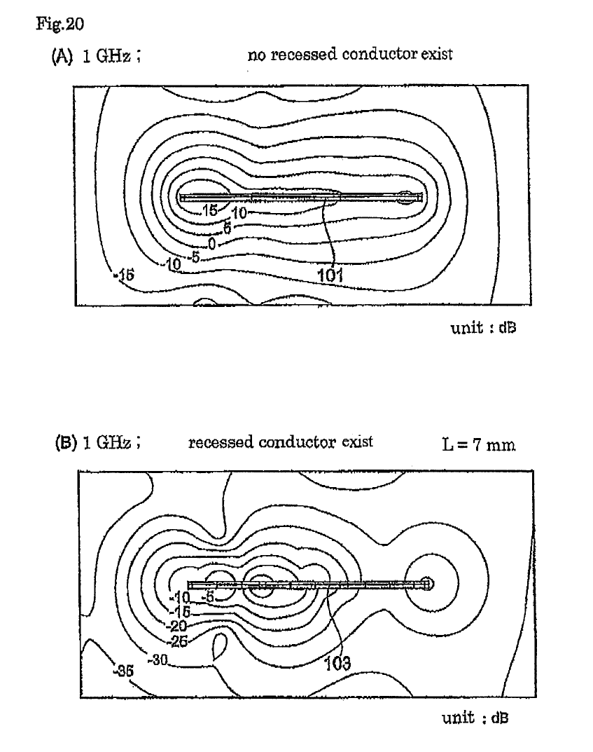

Hereunder, as an example according to the present invention, description will be made, by the use of formulas and data, as regards a suppressing effect of a leakage of magnetic field in the multi-layer printed circuit board explained in the embodiments. FIG. 8 shows an electromagnetic field simulation effect of a characteristic of difference of the maximum magnetic field strength, When a length of an interval between the recessed conductors or the recessed portions L=3 mm. FIG. 9 shows an electromagnetic field simulation effect of a characteristic of difference of the maximum magnetic field strength, when a length of an interval between the recessed conductors or the recessed portions L=7 mm. FIGS. 10 through 19 show distribution views of 1 through 10 GHz magnetic field strength in the multi-layer printed circuit board, wherein the length of the interval L=3 mm. FIGS. 20 through 26 show distribution views of 1 through 7 GHz magnetic field strength in the multi-layer printed circuit board, wherein the length of the interval L=7 mm.

FIG. 8 shows an electromagnetic field simulation effect of a characteristic of difference of the maximum magnetic field strength of a plane Z-X at a position separated by 5 mm in an Y direction from the end portion 5 of the board illustrated in FIG. 1, when the length of the interval L=3 mm. In a horizontal (X) axis, frequency is shown from 1 to 10 GHz per each 1 GHz step. In a vertical (Y) axis, difference of the magnetic field strength ΔH is shown. The difference of the magnetic field strength ΔH is a difference value obtained by subtracting the maximum magnetic field strength of the multi-layer printed circuit board having the recessed conductors from the maximum magnetic field strength of the multi-layer printed circuit board having no recessed conductor. In FIG. 8, plus values in the vertical (Y) axis represent effects of suppressing the leakage of magnetic field by the recessed conductors.

In a case that the length of the interval L=3 mm, it is understood that effects of suppressing the leakage of magnetic field can be obtained by the recessed conductors in all over the frequency bands up to 10 GHz. Thus, since the effects of suppressing the leakage of magnetic field can be obtained up to 10 GHz, a relation between a wavelength of 10 GHz, that is, λ10 GHz and the interval L is represented by the following numerical formula.

L(3 mm)<λ10 GHz/8 (1)

FIG. 9 shows an electromagnetic field simulation effect of a characteristic of difference of the maximum magnetic field strength of a plane Z-X at a position separated by 5 mm in an Y direction from the end portion 5 of the board illustrated in FIG. 1, when the length of the interval L=7 mm. In a horizontal (X) axis, frequency is shown from 1 to 10 GHz per each 1 GHz step. In a vertical (Y) axis, difference of the magnetic field strength ΔH is shown. The difference of the magnetic field strength ΔH is a difference value obtained by subtracting the maximum magnetic field strength of the multi-layer printed circuit board having the recessed conductors from the maximum magnetic field strength of the multi-layer printed circuit board having no recessed conductor. In FIG. 9, plus values in the vertical (Y) axis represent effects of suppressing the leakage of magnetic field by the recessed conductors.

In a case that the length of the interval L=7 mm, it is understood that effects of suppressing the leakage of magnetic field can be obtained by the recessed conductors in all over the frequency bands up to 7 GHz. Under this situation, a frequency that is corresponding to the above numerical formula (1) and that the length L (7 mm) becomes λ/8 is 5 GHz. The effects up to 7 GHz has been obtained in FIG. 9. However, if safety of design is considered, a relation between a wavelength of 5 GHz, that is, λ5 GHz and the interval L is represented by the following numerical formula.

L(7 mm)<λ5 GHz/8 (2)

In view of the effects of suppressing the leakage of magnetic field illustrated in FIGS. 8 and 9, the leakage of magnetic field from the end portion of the board can be suppressed by making a length of each interval between the recessed conductors be less than λ/8 (λ is defined as a wavelength of higher harmonic frequency). An operation signal has a basic operable frequency factor and a higher harmonic frequency factor that is integer double of the operable frequency. In a case of a rectangular wave, the rectangular wave includes a higher harmonic frequency factor of approximately three times to ten times as much as the operable frequency. For example, radiation of electromagnetic waves up to the maximum higher harmonic frequency 5 GHz can be suppressed by providing recessed conductors with the interval L=7 mm, as described above. Further, radiation of electromagnetic waves up to the maximum higher harmonic frequency 10 GHz can be suppressed by providing recessed conductors with the interval L=3 mm.

In a case that the maximum higher harmonic frequency is, for example, 40 GHz, the interval L between the recessed conductors becomes λ/8≈1 mm. Accordingly, radiation of electromagnetic waves up to the maximum higher harmonic frequency 40 GHz can be suppressed by providing recessed conductors with the interval L=1 mm. Thus, radiation of electromagnetic waves from the multi-layer printed circuit board can be suppressed by providing recessed conductors with the interval of λ/8 of higher harmonic frequency waves radiated from the multi-layer printed circuit board.

FIG. 10 shows an electromagnetic field simulation effect of distribution of 1 GHz magnetic field strength of a plane Z-X at a position separated by 5 mm in an Y direction from the end portion of the board illustrated in FIG. 1. FIG. 10 shows the distribution of magnetic field strength simplified into per each 5 dB step. An upper figure (A) shows the distribution of magnetic field strength in a case that no recessed conductor is provided in the end portion of the board. It is understood that strength of magnetic field leaked from the multi-layer printed circuit board 101 in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 15 dB down to −10 dB. Namely, it is understood that the effect of suppressing leakage of magnetic field by providing the recessed conductors can be obtained also in the distribution of magnetic field strength.

FIG. 11 shows an electromagnetic field simulation effect of distribution of 2 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 25 dB down to 20 dB. Namely, it is understood that the effect of suppressing leakage of magnetic field by providing the recessed conductors can be obtained also in the distribution of magnetic field strength.

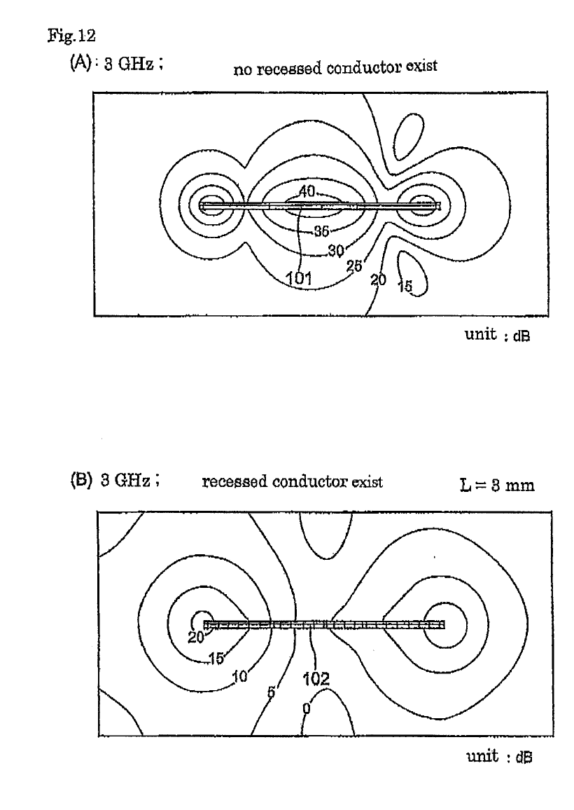

FIG. 12 shows an electromagnetic field simulation effect of distribution of 3 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 40 dB down to 20 dB. Namely, it is understood that the effect of suppressing leakage of magnetic field by providing the recessed conductors can be obtained also in the distribution of magnetic field strength.

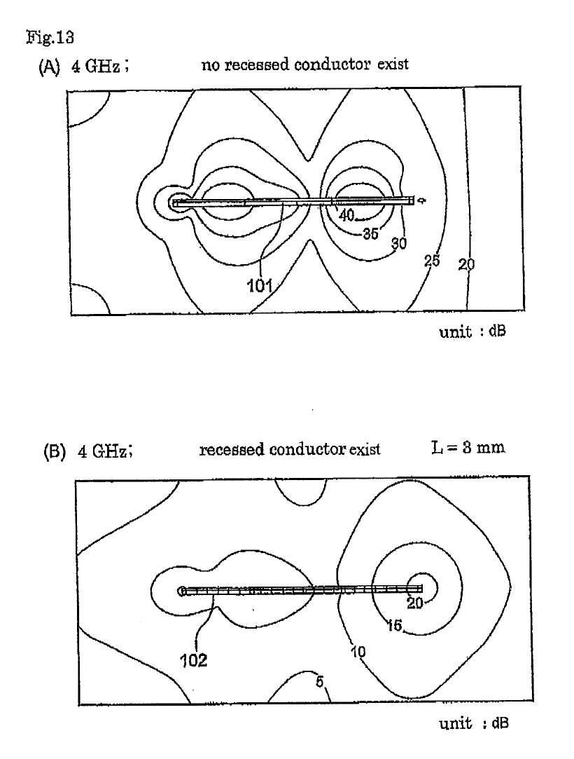

FIG. 13 shows an electromagnetic field simulation effect of distribution of 4 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 40 dB down to 20 dB. Namely, it is understood that the effect of suppressing leakage of magnetic field by providing the recessed conductors can be obtained also in the distribution of magnetic field strength.

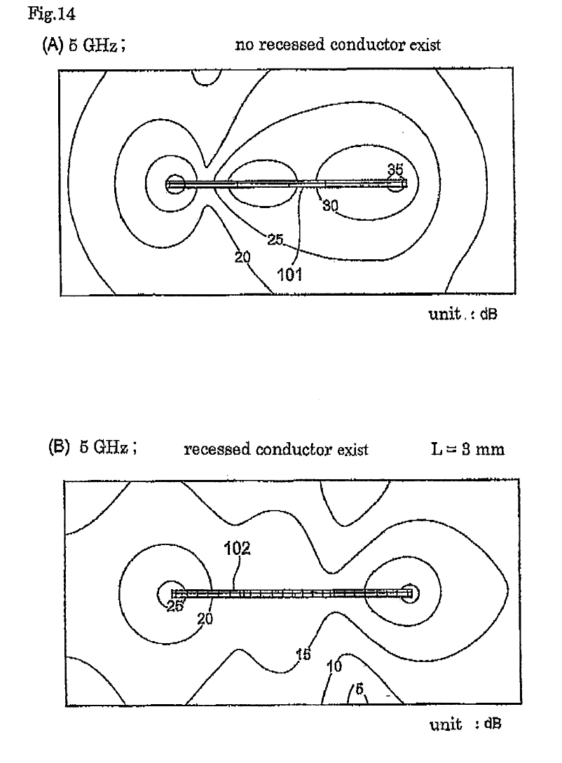

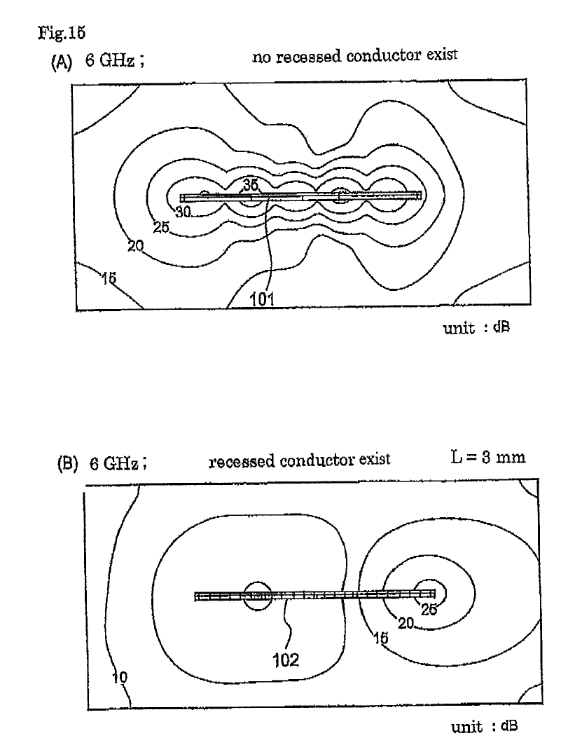

FIG. 14 shows an electromagnetic field simulation effect of distribution of 5 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 35 dB down to 25 dB. Namely, it is understood that the effect of suppressing leakage of magnetic field by providing the recessed conductors can be obtained also in the distribution of magnetic field strength.

FIG. 15 shows an electromagnetic field simulation effect of distribution of 6 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 35 dB down to 25 dB. Namely, it is understood that the effect of suppressing leakage of magnetic field by providing the recessed conductors can be obtained also in the distribution of magnetic field strength

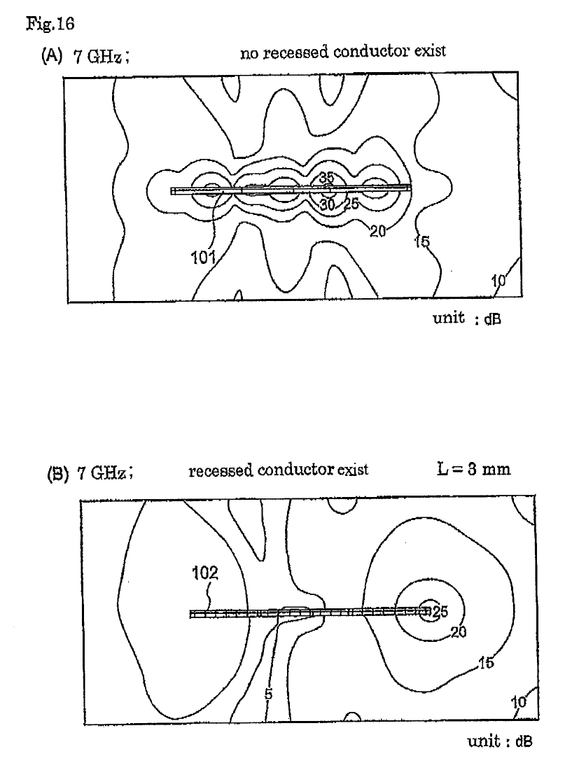

FIG. 16 shows an electromagnetic field simulation effect of distribution of 7 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 35 dB down to 25 dB. Namely, it is understood that the effect of suppressing leakage of magnetic field by providing the recessed conductors can be obtained also in the distribution of magnetic field strength.

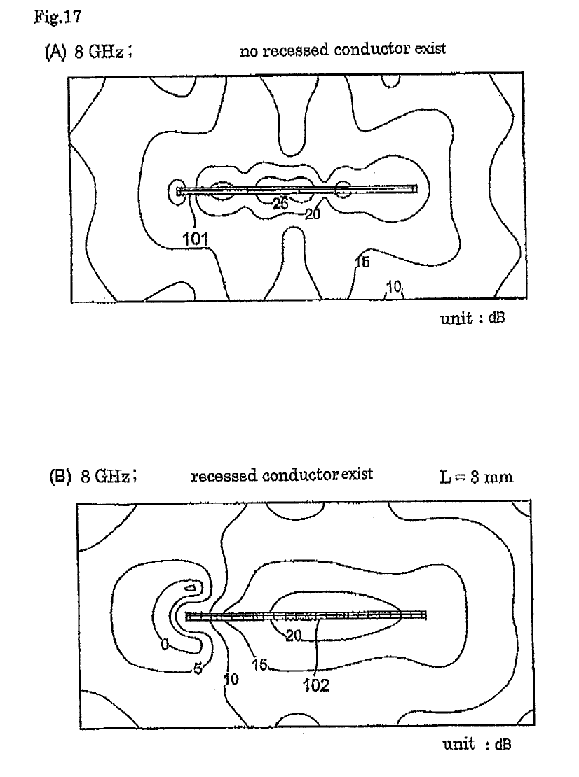

FIG. 17 shows an electromagnetic field simulation effect of distribution of 8 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 25 dB down to 20 dB. Namely, it is understood that the effect of suppressing leakage of magnetic field by providing the recessed conductors can be obtained also in the distribution of magnetic field strength.

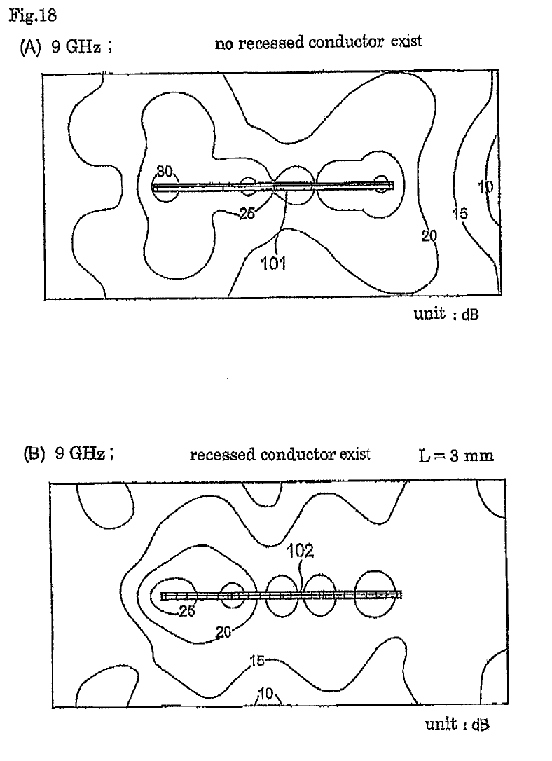

FIG. 18 shows an electromagnetic field simulation effect of distribution of 9 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 30 dB down to 25 dB. Namely, it is understood that the effect of suppressing leakage of magnetic field by providing the recessed conductors can be obtained also in the distribution of magnetic field strength.

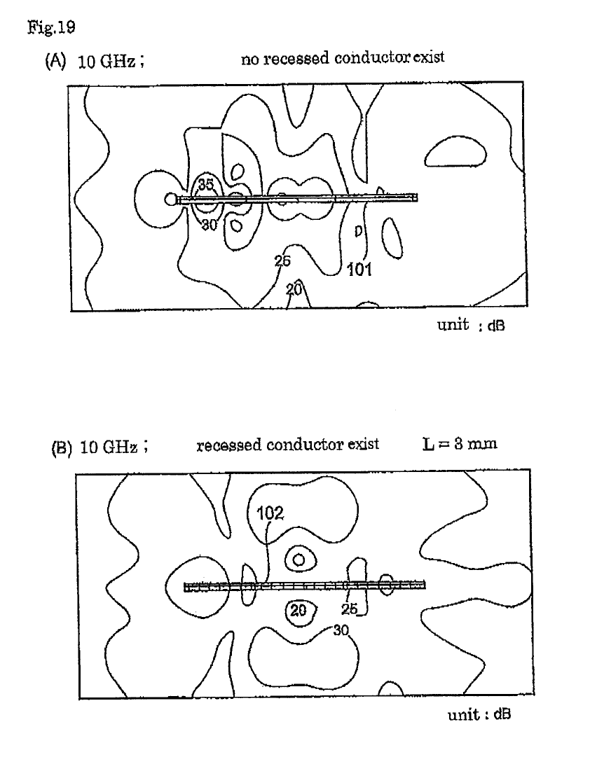

FIG. 19 shows an electromagnetic field simulation effect of distribution of 10 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=3 mm. Compared with the upper figure (A), it is understood in the distribution of magnetic field strength illustrated in the lower figure (B) that the maximum magnetic field strength is reduced from 35 dB down to 30 dB around the multi-layer printed circuit board. Namely, it is understood that the effect of suppressing leakage of magnetic field by providing the recessed conductors can be obtained also in the distribution of magnetic field strength.

FIG. 20 shows an electromagnetic field simulation effect of distribution of 1 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 15 dB down to −5 dB. Namely, it is understood that the effect of suppressing leakage of magnetic field by providing the recessed conductors can be obtained also in the distribution of magnetic field strength.

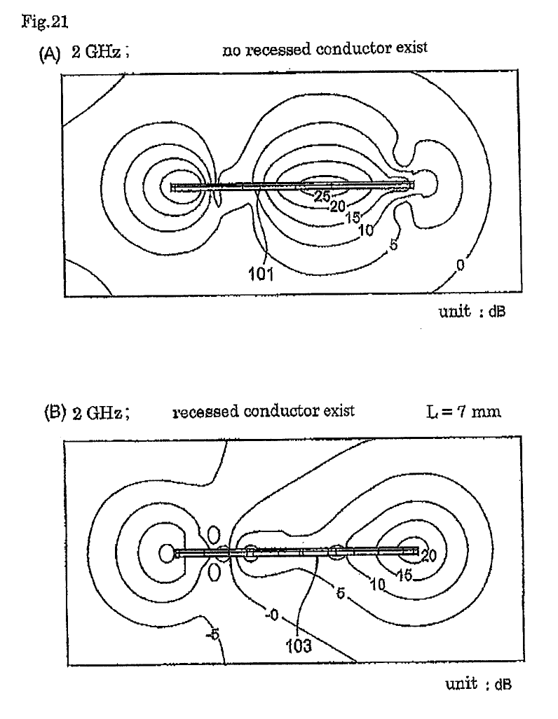

FIG. 21 shows an electromagnetic field simulation effect of distribution of 2 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 25 dB down to 20 dB around the multi-layer printed circuit board. Namely, it is understood that the effect of suppressing leakage of magnetic field by providing the recessed conductors can be obtained also in the distribution of magnetic field strength.

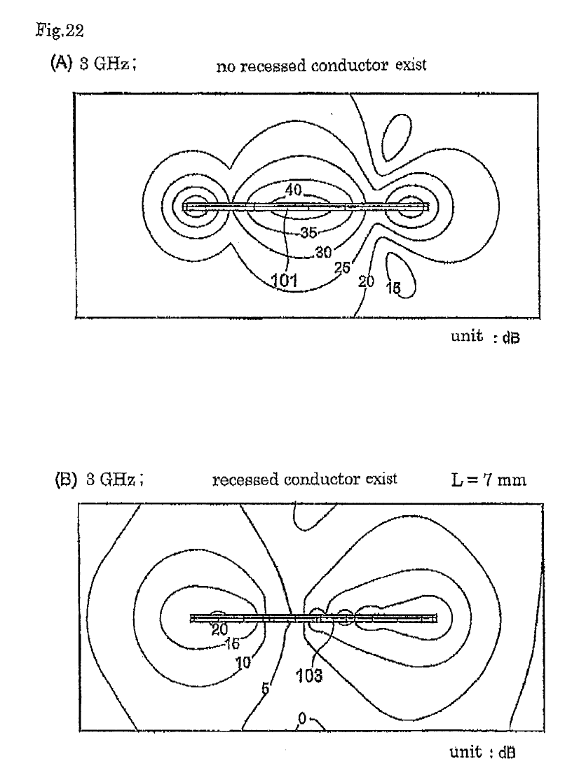

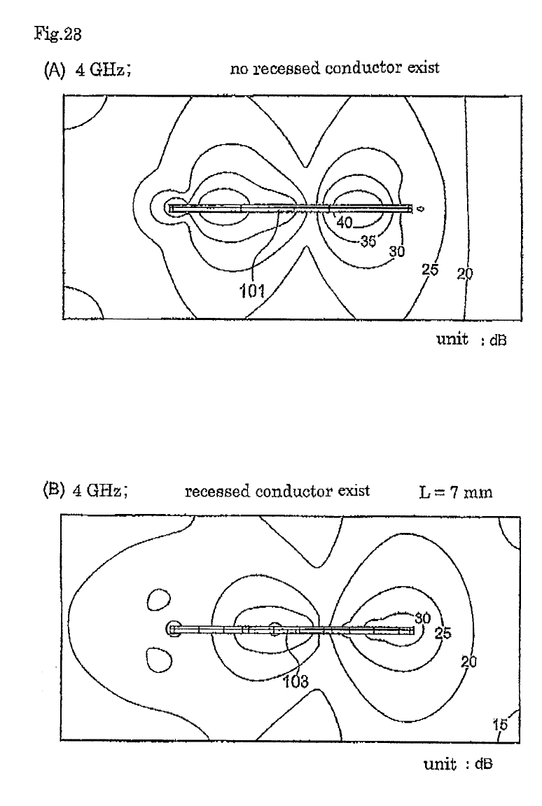

FIG. 22 shows an electromagnetic field simulation effect of distribution of 3 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 40 dB down to 20 dB. Namely, it is understood that the effect of suppressing leakage of magnetic field by providing the recessed conductors can be obtained also in the distribution of magnetic field strength.

FIG. 23 shows an electromagnetic field simulation effect of distribution of 4 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 40 dB down to 30 dB. Namely, it is understood that the effect of suppressing leakage of magnetic field by providing the recessed conductors can be obtained also in the distribution of magnetic field strength.

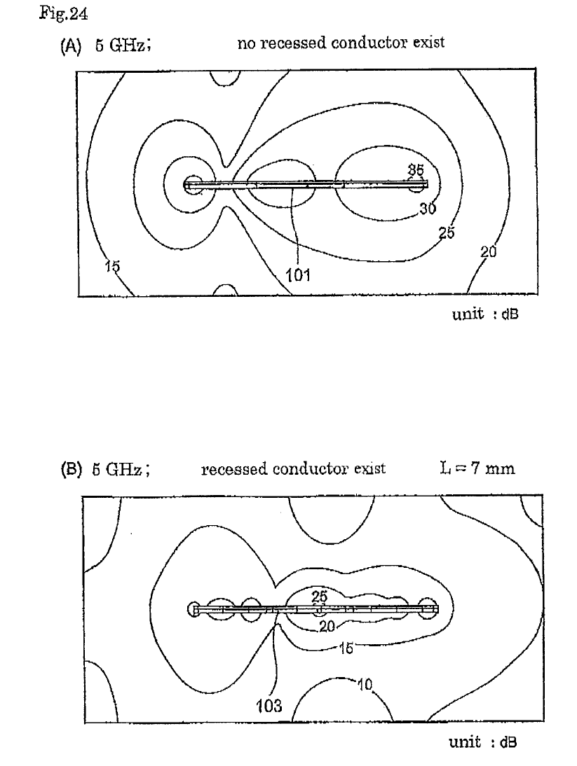

FIG. 24 shows an electromagnetic field simulation effect of distribution of 5 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 35 dB down to 25 dB. Namely, it is understood that the effect of suppressing leakage of magnetic field by providing the recessed conductors can be obtained also in the distribution of magnetic field strength.

FIG. 25 shows an electromagnetic field simulation effect of distribution of 6 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 35 dB down to 25 dB. Namely, it is understood that the effect of suppressing leakage of magnetic field by providing the recessed conductors can be obtained also in the distribution of magnetic field strength.

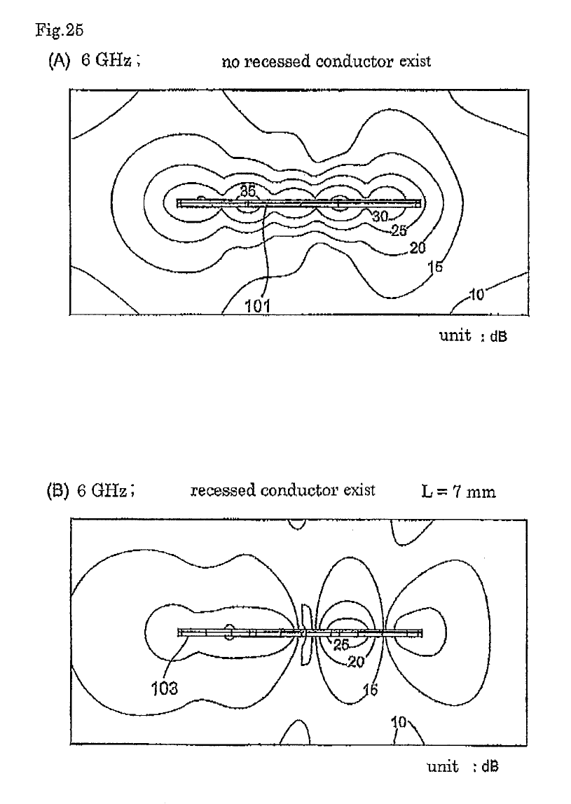

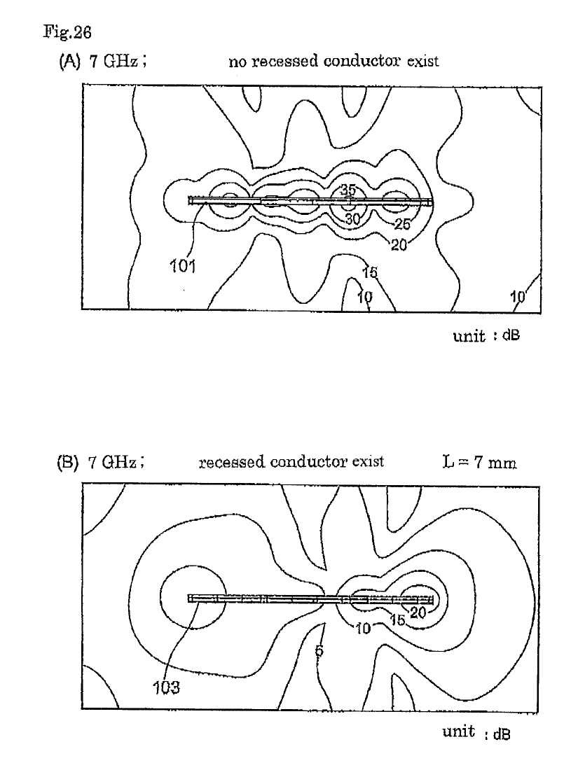

FIG. 26 shows an electromagnetic field simulation effect of distribution of 7 GHz magnetic field strength of a plane Z-X at a position separated by 5 mm in an Y direction from the end portion of the board illustrated in FIG. 1. An upper figure (A) shows the distribution of magnetic field strength in a case that no recessed conductor is provided in the end portion of the board. It is understood that strength of magnetic field leaked from the multi-layer printed circuit board in a position is reduced as the position becomes remote from the board. A lower figure (B) shows the distribution of magnetic field strength in a case that recessed conductors are provided in the end portion of the board with the interval L=7 mm. Compared with the upper figure (A), it is understood in the distribution of magnetic field strength illustrated in the lower figure (B) that the maximum magnetic field strength is reduced from 35 dB down to 20 dB. Namely, it is understood that the effect of suppressing leakage of magnetic field by providing the recessed conductors can be obtained also in the distribution of magnetic field strength.

As described above, according to a multi-layer printed circuit board of the present invention, the multi-layer printed circuit board is shielded by a plurality of the recessed conductors provided in the end portion of the board. Thereby, an effect of suppressing a leakage of the magnetic field can be obtained. The interval between a plurality of the recessed conductors is not larger than λ/8 of a higher harmonic frequency as an operable frequency. The signal layer is shielded by the upper adjacent and the lower adjacent ground layers and the recessed conductors at the end portion of the board, so that a leakage of the magnetic field can be suppressed. The standard rule of radiation noise can be satisfied in an electronic device mounting apparatus on which the multi-layer printed circuit board of the present invention is mounted, since the leakage of the magnetic field from the end portion of the board can be suppressed.

As described above, the present invention was explained concretely based on embodiment thereof. However, the present invention is not restricted to those embodiments. It is possible to put the present invention into practice in various other manners so far as those manners do not exceed the scope of the present invention. It is needless to say that such other manners are included in the present invention.

1. A multi-layer printed circuit board comprising:
a plurality of ground layers;
at least one signal layer;
said signal layer in which a signal pattern is wired at an end portion of the multi-layer printed circuit board being sandwiched between upper adjacent and lower adjacent ground layers; and
said upper adjacent and lower adjacent ground layers being connected to each other by a recessed conductor at the end portion thereof.

2. The multi-layer printed circuit board as claimed in claim 1, wherein a plurality of said recessed conductors are provided.

3. The multi-layer printed circuit board as claimed in claim 2, wherein an interval between said recessed conductors is not larger than λ/8 of a higher harmonic frequency as an operable frequency.

4. A multi-layer printed circuit board comprising:
a plurality of ground layers;
at least one power supply layer;
said power supply layer in which a power supply pattern is wired at an end portion of the multi-layer printed circuit board being sandwiched between upper adjacent and lower adjacent ground layers; and
said upper adjacent and lower adjacent ground layers being connected to each other by a recessed conductor at the end portion thereof.

5. The multi-layer printed circuit board as claimed in claim 4, wherein a plurality of said recessed conductors are provided.

6. The multi-layer printed circuit board as claimed in claim 5, wherein an interval between said recessed conductors is not larger than λ/8 of a higher harmonic frequency as an operable frequency.

7. A work board comprising:
a plurality of multi-layer printed circuit boards located on said work board;
each of said a plurality of multi-layer printed circuit boards having:
a plurality of ground layers, at least one signal layer,
said signal layer in which a signal pattern is wired at an end portion of the multi-layer printed circuit board being sandwiched between upper adjacent and lower adjacent ground layers, and
said upper adjacent and lower adjacent ground layers being connected to each other at the end portion of said each of said a plurality of multi-layer printed circuit boards by a plurality of cut holes which have been through-hole plated.

8. The multi-layer printed circuit board obtained from the work board as claimed in claim 7, wherein said work board is scribed between said a plurality of cut holes and divided into said each of said a plurality of multi-layer printed circuit boards.

9. The multi-layer printed circuit board as claimed in claim 8, wherein an interval between said a plurality of cut holes is not larger than λ/8 of a higher harmonic frequency as an operable frequency.

10. A work board comprising:
a plurality of multi-layer printed circuit boards located on said work board;
each of said a plurality of multi-layer printed circuit boards having:
a plurality of ground layers,
at least one power supply layer,
said power supply layer in which a power supply pattern is wired at an end portion of the multi-layer printed circuit board being sandwiched between upper adjacent and lower adjacent ground layers, and
said upper adjacent and lower adjacent ground layers being connected to each other at the and portion of said each of said a plurality of multi-layer printed circuit boards by a plurality of cut holes which have been through-hole plated.

11. The multi-layer printed circuit board obtained from the work board as claimed in claim 10, wherein said work board is scribed between said a plurality of cut holes and divided into said each of said a plurality of multi-layer printed circuit boards.

12. The multi-layer printed circuit board as claimed in claim 11, wherein an interval between said a plurality of cut holes is not larger than λ/8 of a higher harmonic frequency as an operable frequency.
